(19) United States
(12) Patent Application Publication
(10) Pub. No.: US 2009/0134390 A1
(43) Pub. Date: May 28, 2009

(54) Image forming apparatus

(75) Inventors: Jun Kodama, Ashigarakami-gun (JP); Masaya Nakayama, Ashigarakami-gun (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/292,365

(22) Filed: Nov. 18, 2008

(30) Foreign Application Priority Data
Nov. 22, 2007 (JP) 2007-302730

(51) Int. Cl. H01L 27/12

(52) U.S. Cl. 257/43; 257/E27.112

(57) ABSTRACT

An image forming apparatus including a substrate 12, pixel regions 14 that are arrayed on the substrate, data-input portions 38 and 40 that input image data to the pixel regions, and a current-supply portion 42 that supplies charge to the pixel regions. The pixel regions each include: thin-film transistors 30, 32 including a gate electrode 44, a gate insulating film 46, an active layer 48, a source electrode 50, and a drain electrode 52; a capacitor 34 that is electrically connected to the drain electrode and that accumulates charge; and a pixel electrode 36 that is electrically connected to the drain electrode and to the capacitor such that charged particles are electrostatically attracted to a pixel region by movement of charge accumulated in the capacitor to the pixel electrode constituting the pixel region. The active layer of the thin film transistor is formed from a material that includes an oxide semiconductor. A flexible substrate is preferably used.

### CROSS REFERENCE TO RELATED APPLICATION

This application claims priority under 35USC 119 from Japanese Patent Application No. 2007-302730, the disclosure of which is incorporated herein by reference.

### BACKGROUND OF THE INVENTION

1. Field of the Invention

The present invention relates to an image forming apparatus, and more specifically to an image forming apparatus that forms an image using charged particles and is not provided with a photoreceptor and a light-exposing unit.

2. Description of the Related Art

There are image forming apparatuses which form an image by attaching a toner to a photoreceptor. For example, a latent image is formed by light-exposure of a charged photoreceptor, an image (toner image) is formed by attaching toner to portions of lowered electrical potential, then the formed image is transferred to a transfer medium such as paper. In addition to a photoreceptor, such apparatuses using photoreceptors require a charging unit, an exposing unit, a developing unit, a transfer unit, and also an erasing unit, for erasing charge form the surface of the photoreceptor after transfer, and a cleaning brush or the like for removing any residual toner etc.

There are, on the other hand, apparatuses proposed for forming an image with toner not provided with a photoreceptor and an exposing unit (see Japanese Patent Application Laid-Open (JP-A) No. 11-288152). In such image forming apparatuses, pixel regions are arranged in a matrix shape on a substrate, the pixel regions respectively including a high voltage transistor formed from amorphous silicon, a high voltage capacitor, a data input portion, and an electrode (conductor). A latent image is then formed by selectively generating electrical potentials in the pixel regions, based on image data supplied from a computer or the like and, after toner is attracted thereto, the toner is transferred to paper.

With an image forming apparatus formed in advance with pixel regions on a substrate, as described above, provision of a photoreceptor and an exposing unit becomes unnecessary. However, high voltage transistors and high voltage capacitors are required, and a reduction in image quality readily arises due to localized abnormal electrical discharge. In addition, a high temperature process is required in order to produce transistors using amorphous silicon, and consequently it is difficult to use a flexible substrate such as one formed from plastic, with it being difficult to achieve miniaturization and weight reduction of such an apparatus.

### SUMMARY OF THE INVENTION

The present invention has been made in view of the above circumstances and provides the following image forming apparatus.

According to a first aspect of the present invention is provided an image forming apparatus including: a substrate; a plurality of pixel regions arrayed on the substrate; an input portion that inputs image data to the pixel regions; and an electrical supply portion that supplies charge to the pixel regions, the pixel regions each comprising: a thin film transistor comprising a gate electrode, a gate insulating film, an active layer, a source electrode, and a drain electrode; a capacitor that is electrically connected to the drain electrode and that accumulates charge; and a pixel electrode that is electrically connected to the drain electrode and to the capacitor, such that charged particles are electrostatically attracted to a pixel region by movement of charge accumulated in the capacitor to the pixel electrode constituting the pixel region, and the active layer of the thin film transistor being formed with a material that includes an oxide semiconductor.

### BRIEF DESCRIPTION OF THE DRAWINGS

FIG. 1 is a schematic configuration diagram showing an example (first exemplary embodiment) of an image forming apparatus according to the present invention;

FIG. 2 is a plan view showing an example of a matrix of pixel regions;

FIG. 3A is a diagram showing an example of a circuit configuration of a single pixel region in a charge-accumulated state;

FIG. 3B is a diagram showing an example of a circuit configuration of a single pixel region in a state in which the charge has moved toward charged particles;

FIG. 4 is a diagram showing another example of a circuit configuration of a single pixel region;

FIG. 5 is a schematic diagram showing an example of a configuration of a thin film transistor included in a pixel region;

FIG. 6 is a schematic cross-section showing an example of a thin film transistor (bottom gate type) using a double layer structure for an active layer;

FIG. 7 is a schematic cross-section showing another example of a thin film transistor (top gate type) using a double layer structure for an active layer; and

FIG. 8 is a schematic configuration diagram showing another example (second exemplary embodiment) of an image forming apparatus according to the present invention.

### DETAILED DESCRIPTION OF THE INVENTION

Herebelow, an example of an exemplary embodiment of the present invention will be described in detail with reference to the drawings.

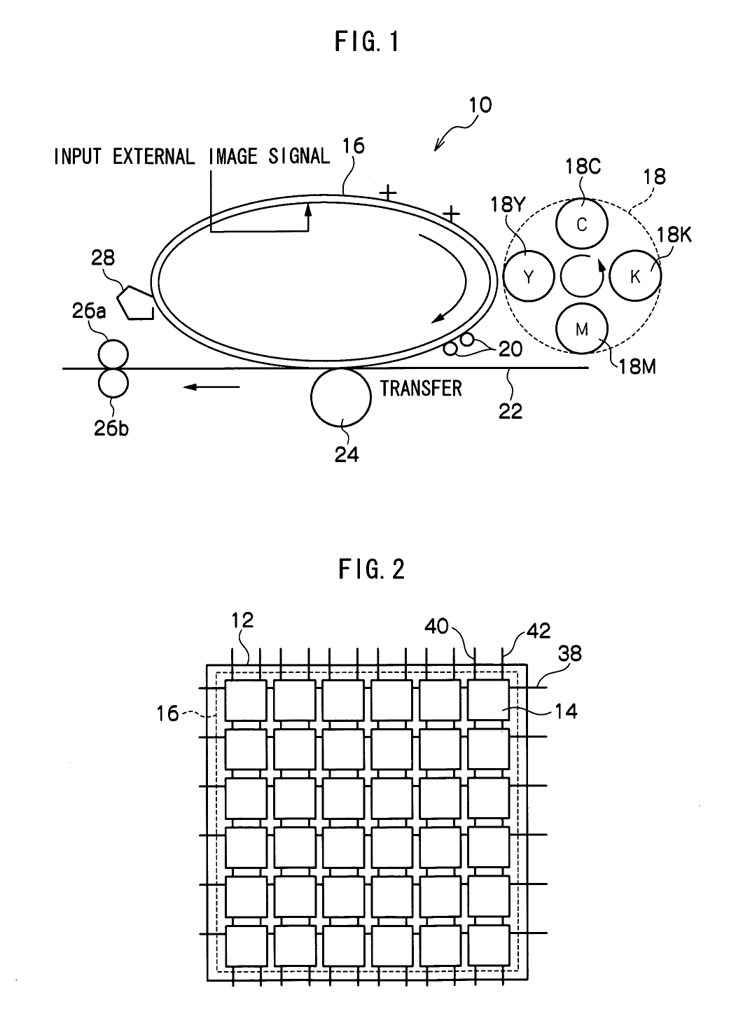

FIG. 1 shows schematically an example (first exemplary embodiment) of an image forming apparatus according to the present invention and FIG. 2 shows an expanded portion of an image-forming section 16. This image forming apparatus 10 is provided with a substrate 12, plural pixel regions 14 arrayed on the substrate 12, data-input portions 38 and 40 that input image data into the pixel regions 14, and current-supply portions 42 that supply charge to the pixel regions 14. In the image-forming section 16, as shown in FIG. 2, the pixel regions 14 are regularly arrayed on the substrate 12. A developing device 18, a transfer roll 24, and a cleaning member 28 etc. are also provided at the periphery of the image-forming section 16.

Substrate

The material of the substrate 12 is not particularly limited, and examples thereof include: inorganic materials, such as, for example, YSZ (yttrium-stabilized zirconia), glass and the like; and organic materials, such as polyesters such as polyethylene terephthalate, polybutylene terephthalate, polyethylene naphthalate, synthetic resins such as polystyrene, polycarbonate, polyethersulfone, polyarylate, allyl diglycol carbonate, polyimide, poly cycloolefines, norbornene resin, and poly (chlorotrifluoroethylene). Preferable organic materials are those with excellent heat resistance, dimensional stability, solvent resistance, electric insulation properties, processability, low gas permeability, and low moisture absorption.

In particular a flexible substrate is preferably used for the substrate 12 in the present invention. An organic plastic with high light transmittance is preferably used as the material for the flexible substrate 12, and plastic films of the above organic materials can be used therefor. An insulation layer is preferably provided to the substrate 12 of plastic film form when the insulation properties thereof are insufficient, a gas barrier layer is preferably provided thereto to prevent moisture and oxygen transmission, and an undercoating layer or the like is preferably provided to improve the flatness of the substrate 12 of plastic film form and its adherence to an electrode or an active layer 48.

When using the flexible substrate 12, the thickness thereof depends on the properties of the material used, but a thickness enabling support to be assured of the pixel regions 14 formed on the substrate 12 and also allowing the substrate 12 to bend freely is preferable. For example, the thickness may be from 10 μm to 2 mm, and is preferably from 100 μm to 0.5 mm.

Freely shaping by bending and rounding etc. is enabled by the utilization of such a flexible substrate 12 made from plastic. A rotatable elliptical shaped image-forming section 16, as shown in FIG. 1, is also therefore possible, enabling miniaturization and reduction in weight to be achieved for the image forming apparatus 10.

It is also preferable to use a transparent substrate. For example, by providing a light irradiation unit on the inside of the image-forming section 16, so that light can be irradiated to the pixel regions 14 as a whole (to the image-forming section 16) through the transparent substrate 12, it is possible to carry out charge erasure readily and uniformly to all of the pixel regions 14. As described below, the pixel regions 14 are formed so as to include a TFT (thin film transistor) semiconductor for controlling charge movement, and one or other of electrons and holes generated within the semiconductor by the light irradiation to the TFT can be attracted to residual charge, and any charge remaining on the surface of the semiconductor can be thus eliminated.

Pixel Regions

There is no particular limitation to the arrangement (array) of pixel regions 14 on the substrate 12, however, for example, arraying in a matrix shape on the substrate 12 as shown in FIG. 2 is advantageous for forming high precision images. The number of pixel regions 14 can be determined according to the required image quality, however, for example, this number can be set to 200 ppi (pixels per inch) or above.

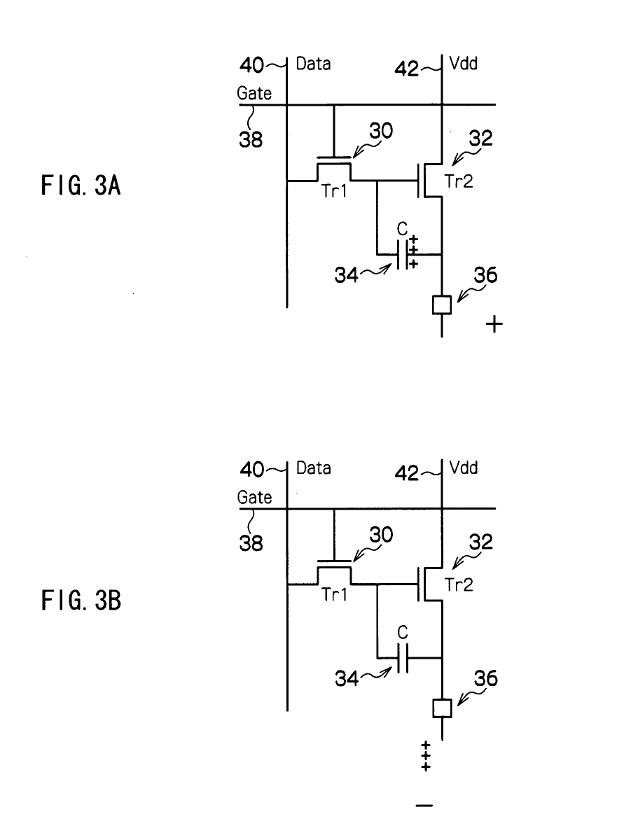

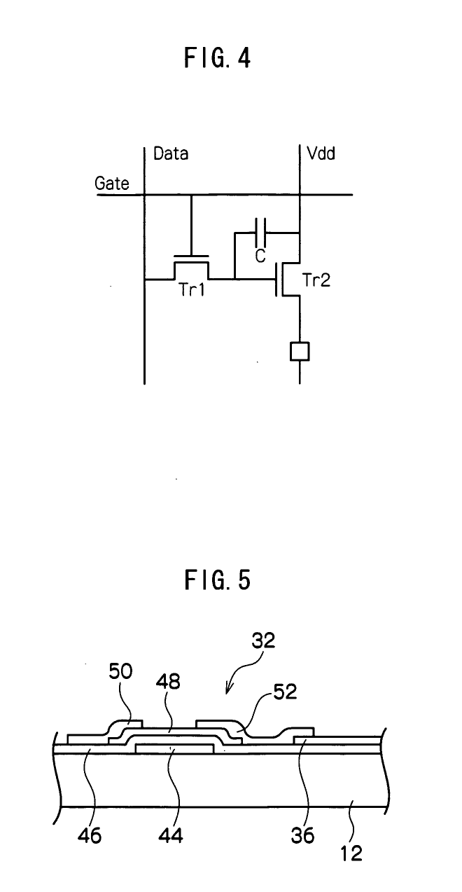

FIG. 3A and FIG. 3B show schematically an example of a circuit configuration of a single one of the pixel regions 14. Two thin film transistors 30, 32, a capacitor 34, and a pixel electrode 36 are provided in each of the pixel regions 14. In addition, although at least a single thin film transistor (switching element) is required to be formed per one of the pixel regions 14, two thin-film transistors may be provided in a single one of the pixel regions 14, as shown in FIG. 3A, and three or more thereof may also be provided. If plural thin-film transistors 30, 32 are provided in a single one of the pixel regions 14, more precise control is obtainable, enabling, for example, easy erasure of residual charge, etc. Moreover, a suitable design can be adopted for the arrangement of the thin-film transistors 30, 32, and the capacitor 34 in a single one of the pixel regions 14. For example, even when two of the thin-film transistors 30, 32 are provided in a single one of the pixel regions 14, the arrangement thereof is not limited to the arrangement shown in FIG. 3A, and can also be, for example, as shown in FIG. 4.

FIG. 5 is a schematic cross-section showing an example of a configuration of the thin film transistor 32 included in each of the pixel regions 14. The thin film transistor 32 is configured with a gate electrode 44, a gate insulating film 46, the active layer 48, a source electrode 50, and a drain electrode 52. The other thin-film transistor 30 is similarly configured.

Gate Electrode

Preferable examples of materials for forming the gate electrode 44 include: metals, such as Al, Mo, Cr, Ta, Ti, Au, and Ag; alloys, such as Al—Nd, and APC; metal oxide conducting films, such as tin oxide, zinc oxide, indium oxide, indium tin oxide (ITO), and indium zinc oxide (IZO); conductive organic compounds, such as polyaniline, polythiophene, and polypyrrole; and mixtures thereof.

There are no particular limitations to the method of forming the gate electrode 44, and, in consideration of the applicability to the material used and the material of the substrate 12, a suitable method may be selected for forming the gate electrode 44 on the substrate 12 from methods such as: wet methods, such as printing methods and coating methods; physical methods, such as vacuum deposition methods, sputtering methods, ion plating methods; and chemical methods, such as CVD and plasma CVD methods. If ITO is selected, for example, forming can be carried out by a direct current or an RF-sputtering method, vacuum deposition method, ion plating method or the like. The gate electrode 44 can be formed by a wet process when a conductive organic compound is selected for the material of the gate electrode 44. The thickness of the gate electrode 44 can be set, for example, to be from 10 nm to 1000 nm.

Gate Insulating Film

Examples of materials that can be used to configure the gate insulating film 46 include insulators such as SiO₂, SiNₓ, SiON, Al₂O₃, Y₂O₃, Ta₂O₅, HfO₂, and mixed crystal compounds containing at least two or more compounds thereof. Moreover, a polymer insulating material like polyimide can also be used as the gate insulating film 46.

The thickness of the gate insulating film 46 is preferably 10 nm to 10 μm. The thickness of the gate insulating film 46 needs to be reasonably thick in order to both reduce leakage current and raise voltage resistance. However, as the thickness of the gate insulating film 46 is thickened, this results in the driving voltage of the TFT being raised. Consequently the thickness of the gate insulating film 46 is more preferably 50 nm to 1000 nm when an inorganic insulator is used and is more preferably 0.5 μm to 5 μm when a polymer insulating material is used. In particular, since low voltage TFT driving is possible even with a thick film thickness if a high permittivity insulator like HfO₂ is used for the gate insulating film 46, such a gate insulating film 46 is particularly preferable.

Active Layer

The active layer 48 is formed with a material containing an oxide semiconductor. By forming the active layer 48 with an oxide semiconductor the charge mobility can be much higher, as compared with an active layer of amorphous silicon, and the driving with a lower voltage is possible. Moreover, using an oxide semiconductor enables the active layer 48 to be formed with high transparency and with flexibility. Therefore, it is also advantageous from the standpoint of readily attaining charge erasure by light-irradiation and miniaturization of the device when using the substrate 12 which is transparent and flexible. Moreover, an oxide semiconductor, and in particular an amorphous oxide semiconductor, is particularly advantageous when using a flexible resin substrate 12 such as a plastic substrate, since a uniform film can be formed at low temperature (for example at ambient temperature).

Preferably oxide semiconductors for forming the active layer 48 are oxides including at least one of In, Ga, or Zn (such as Zn—O oxides), oxides including two or more of In, Ga, or Zn (such as In—Zn—O oxides, In—Ga—O oxides, Ga—Zn—O oxides) are more preferable, and oxides including In, Ga and Zn are even more preferable. Preferable oxide semiconductors for In—Ga—Zn—O oxides are those oxide semiconductors whose composition in a crystalline state is represented by the formula InGaO₃ (ZnO)ₘ (where m is a positive integer less than 6), and in particular InGaZnO₄ is more preferable. The characteristics of compositions of such amorphous oxide semiconductors are that they tend to show an increase in electron mobility accompanying an increase in electrical conductivity.

The electrical conductivity here refers to a physical property representing the ease of electrical conduction of a substance, and if the carrier density of a substance is n, and the carrier mobility is μ, then the electrical conductivity a of the substance is shown by the equation below.

σ=neμ

When the active layer 48 is an n-type semiconductor the carrier is an electron, and the carrier density is the electron carrier density, and the carrier mobility represents the electron mobility. In a similar manner, when the active layer 48 is a p-type semiconductor the carrier is a hole, the carrier density is the hole carrier density, and the carrier mobility represents the hole mobility. It should be noted that the carrier density and carrier mobility of the substance can be derived from hole measurements.

By measuring the sheet resistance of a film of known thickness, the electrical conductivity of the film can be derived. The electrical conductivity of a semiconductor changes with temperature, and the electrical conductivities within the present application represents electrical conductivities at room temperature (20° C.).

Oxide semiconductors forming the active layer 48 are preferably n-type oxide semiconductors including at least one of In, Ga, or Zn as stated above, however, a p-type oxide semiconductor such as ZnO/Rh₂O₃, CuGaO₂, or SrCu₂O₂ can also be used for the active layer 48.

The electrical conductivity of the active layer 48 is preferably higher in the vicinity of the gate insulating film 46 of the active layer 48 than in the vicinity of the source electrode 50 and the drain electrode 52 thereof. More preferably the ratio of the electrical conductivity in the vicinity of the gate insulating film 46 to the electrical conductivity in the vicinity of the source electrode 50 and the drain electrode 52 (electrical conductivity in the vicinity of the gate insulating film 46/ electrical conductivity in the vicinity of the source electrode 50 and the drain electrode 52) is preferably from 10¹ to 10¹⁰, and more preferably from 10² to 10⁸. The electrical conductivity in the boundary of the gate insulating film 46 of the active layer 48 is preferably 10⁴ Scm⁻¹ or more but less than 10² Scm⁻¹, and is more preferably 10⁻¹ Scm⁻¹ or more but less than 10² Scm⁻¹.

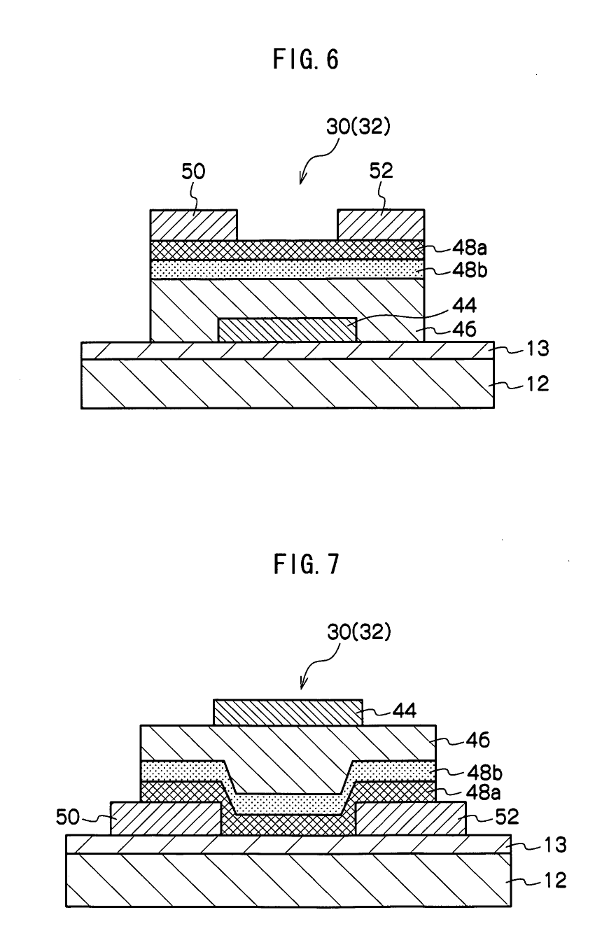

The active layer 48 can also be formed from plural layers. For example, as shown in FIG. 6, it is preferable to configure the active layer 48 with at least a first region 48a, and a second region 48b having an electrical conductivity that is higher than that of the first region 48a, with the second region 48b in contact with the gate insulating film 46, and the first region 48a electrically connected to at least one of the source electrode 50 and the drain electrode 52. More preferably, the ratio of the electrical conductivity of the second region 48b to the electrical conductivity of the first region 48a (the electrical conductivity of the second region 48b/the electrical conductivity of the first region 48a) is preferably from 10¹ to 10¹⁰, and more preferably from 10² to 10⁸.

The electrical conductivity in the second region 48b is preferably 10⁻⁴ Scm⁻¹ or more but less than 10² Scm⁻¹, and is more preferably 10⁻¹ Scm⁻¹ or more but less than 10² Scm⁻¹. The electrical conductivity in the first region 48a is preferably 10⁻¹ Scm⁻¹ or less, and is more preferably from 10⁻⁹ Scm⁻¹ to 10⁻³ Scm⁻¹.

If a two-layer structure of active layer 48a, 48b is formed from an amorphous oxide semiconductor such as the IGZO described above, a TFT having a high mobility of 10 cm²V⁻¹s⁻¹ or greater and transistor characteristics with an ON/OFF ratio of 10⁶ or above is realizable, and a much lower voltage is achievable.

In the active layer 48 of the present invention, the electrical conductivity of the active layer 48 in the vicinity of the gate insulating film 46 is preferably adjusted to be higher than that in the vicinity of the source electrode 50 and the drain electrode 52 as above. When the active layer 48 is formed from an oxide semiconductor the following method can be used as a method for adjusting the electrical conductivity.

(1) Adjustment by Oxygen Vacancies

It is known that if oxygen vacancies can be induced in an oxide semiconductor then carrier electrons are generated, and the electrical conductivity becomes high. Consequently the electrical conductivity of an oxide semiconductor is controllable by adjusting the quantity of oxygen vacancies. Specific examples of methods for controlling the quantity of oxygen vacancies include controlling the partial pressure of oxygen during film formation, and controlling the oxygen concentration and duration when carrying out post processing after film formation. Specific examples of such post processing include heat treatment at 100° C. or above, oxygen plasma processing, UV ozone processing and the like. Among these methods the method of controlling the oxygen partial pressure during film formation is preferable from the standpoint of productivity. The electrical conductivity of the oxide semiconductor can be controlled by adjusting the oxygen partial pressure during film formation.

(2) Adjustment by Composition Ratio

The electrical conductivity can also be changed by changing the metal composition ratio of the oxide semiconductor. For example, the electrical conductivity decreases as the proportion of Mg increases in a compound InGaZn₁₋ₓMgₓO₄. It is reported that in oxides of the formula (In₂O₃)₁₋ₓ(ZnO)ₓ, when the ratio of Zn/In is 10% or greater, the electrical conductivity decreases as the proportion of Zn increases (pages 34 and 35 of “New Developments of Transparent Electroconductive Films II”, CMC press). Specific methods for changing the composition ratio include, for example, a method of using targets with different composition ratios in a film formation method using sputtering. It is also possible to change the composition ratio of a film by individually adjusting the sputtering rates when multi-target co-sputtering.

(3) Adjustment by Impurities

It is possible to reduce the electron carrier density, namely to make the electrical conductivity low, by adding impurity elements, such as Li, Na, Mn, Ni, Pd, Cu, Cd, C, N, and P. Methods for adding impurities include methods such as carrying out co-deposition of an oxide semiconductor and an impurity element, or using an ion doping method to dope a formed film of oxide semiconductor with ions of an impurity element.

(4) Adjustment by Oxide Semiconductor Material

Adjustment methods for adjusting the electrical conductivity while using the same type of oxide semiconductor have been given in (1) to (3) above, but obviously the electrical conductivity can also be changed by changing the oxide semiconductor material. It is known, for example, that generally SnO₂ oxide semiconductors have a lower electrical conductivity in comparison to In₂O₃ oxide semiconductors. The electrical conductivity is adjustable by changing the oxide semiconductor material in such a manner.

A multi-crystal sintered body of oxide semiconductor may be used as the target in a vapor phase film formation method as the film formation method of the active layer 48. Sputtering methods and pulse-laser deposition methods (PLD methods) are suitably employed among vapor phase film formation methods. Sputtering methods are preferable from the standpoint of mass production.

For example, film formation may be carried out controlling the degree of vacuum and oxygen flow amount by an RF magnetron-sputtering vapor deposition method. The electrical conductivity can be made lower as the oxygen flow amount is made greater.

It should be noted that any of the above methods (1) to (4) may be used on its own as the method for adjusting the electrical conductivity when film forming, or a combination thereof may be employed.

The formed film can be confirmed to be an amorphous film by a known X-ray diffraction method.

The film thickness can be determined by contact type surface profile measurements. The composition ratio can be determined by an RBS (Rutherford Backscattering Spectroscopy) analysis method.

The thickness of the active layer 48 can, for example, be made to be from 5 nm to 100 μm.

Source/Drain Electrodes

The source electrode 50 and the drain electrode 52 are formed after forming the active layer 48. Preferable examples of materials for forming the source electrode 50 and the drain electrode 52 include: metals, such as metals, Al, Mo, Cr, Ta, Ti, Au, and Ag; alloys, such as Al—Nd, and APC; metal oxide conducting films, such as tin oxide, zinc oxide, indium oxide, indium tin oxide (ITO), and indium zinc oxide (IZO); conductive organic compounds, such as polyaniline, polythiophene, and polypyrrole; and mixtures thereof.

The same methods can be employed for the forming methods of the source electrode 50 and the drain electrode 52 as the above forming methods for the gate electrode 44. Moreover, the thickness of the source electrode 50 and the drain electrode 52 can be made, for example, from 10 nm to 1000 nm.

The thin-film transistors 30, 32 included in each of the pixel regions 14 may be any of bottom gate-type or top gate-type transistors. The thin film transistors 30, 32 may be configured, for example as shown in FIG. 7, with stacked layers, in sequence from the substrate 12 side, of: the source/drain electrodes 50, 52; the active layer 48a, 48b; the gate insulating film 46; and the gate electrode 44. There is an insulating film 13 formed on the substrate 12 in FIGS. 6 and 7, with the thin film transistor 30 (32) formed thereon.

Capacitor

The capacitor 34 is electrically connected to the drain electrode 52 and accumulates charge. The charge accumulated in the capacitor 34 is converted into a voltage signal by the thin-film transistors 30, 32 and output. The capacitor 34 can be formed by patterning or the like at the same time as forming the gate electrode 44, the gate insulating film 46, and the source/drain electrodes 50, 52 of the thin-film transistors 30, 32 described above, using photolithography etc.

Pixel Electrode

The pixel electrode 36 is electrically connected to the drain electrode 52 and to the capacitor 34 of the thin-film transistors 30, 32. The charge accumulated in the capacitor 34 (holes in FIG. 3A) enable charged particles 20 to be attracted electrostatically to the pixel electrode 36, by moving to the pixel electrode 36. The pixel electrode 36 can, for example, be formed by patterning at the same time as forming the gate electrode 44, or forming the source/drain electrodes 50, 52, using photolithography etc. Alternatively the pixel electrode 36 can also be formed by a separate process from those used for the thin-film transistors 30, 32.

The electrodes of the thin-film transistors 30, 32 (the gate electrode 44, the source electrode 50 and the drain electrode 52) together with the pixel electrode 36 are preferably formed from a material including an oxide semiconductor. If not only the active layer 48 but also the electrodes 44, 50, 52 for the thin film transistor constituting each of the pixel regions 14 are formed with an oxide semiconductor, then as well as being able to form the thin-film transistors 30, 32 as a whole using low temperature processes, the thin-film transistors 30, 32 can also be formed with high transparency and flexibility. In addition, by also forming the pixel electrode 36 with a material including an oxide semiconductor this ensures that the pixel regions 14 as a whole can be formed by low temperature processes, this being particularly advantageous when the substrate 12 used is flexible.

Specific examples of oxide semiconductors for forming these electrodes include, similar to when forming the active layer 48 as above, n-type oxide semiconductors including at least one of In, Ga, or Zn and p-type oxide semiconductor such as ZnO/Rh₂O₃, CuGaO₂, or SrCu₂O₂.

Data Input Portion and Current-Supply Portion

Each of the pixel regions 14 on the substrate 12 is connected to the data-input portions 38, 40 for inputting image data and to the current-supply portions 42 for supplying charge. In the pixel region 14 shown in FIG. 3A, the gate electrode 44 of the thin film transistor 30 is connected to the gate line 38 and to the data line 40, as the data-input portions, for inputting external image data such as from a computer, scanner etc. In addition, the source electrode 50 of each of the thin-film transistors 30, 32 is connected to the current-supply line 42, as the current-supply portion, for supplying charge.

It should be noted that the wiring-lines 38, 40, 42 may be formed by patterning at the same time as forming each electrode of the thin-film transistors 30, 32, or they may be formed separately therefrom.

These data-input portions 38, 40 and current-supply portion 42 are connected to all of the pixel regions 14, and specific voltages can be selectively applied to the pixel regions 14 on the substrate 12 by control through these wiring-lines 38, 40, 42. The pixel regions 14 can be controlled in a similar way to controls employed in a device using organic EL elements or liquid crystal elements. For example, since the circuit configurations of the pixel regions 14 shown in FIG. 3A, FIG. 3B and FIG. 4 are similar to those used in known active matrix organic EL devices, a latent image can be formed to the image-forming section 16 by similar control thereto.

A wiring line may also be provided in each of the pixel regions 14 for erasing charge prior to carrying out the next image formation. Charge erasure may be undertaken by light irradiation when using a transparent substrate, as described above, however, when for example the substrate is not transparent then charge erasure can be carried out with certainty by providing wiring lines for charge erasure to all of the pixel portions.

After forming the thin-film transistors 30, 32, the capacitor 34 and the pixel electrode 36 etc. on the substrate 12, this is then preferably covered with an insulation film or insulation substrate in order to protect the pixel regions 14. The materials indicated, for example, for the gate insulating film 46 or for the substrate 12 can be used for such an insulation film or insulation substrate.

The image forming apparatus 10 according to the present invention can be manufactured in this manner.

Explanation will now be given of the method for forming images using the image forming apparatus 10.

If pixel regions 14 are arrayed on the flexible substrate 12 by forming the active layer 48 of the thin-film transistors 30, 32 from an oxide semiconductor such as an IGZO film or the like then it is possible to rotate the image-forming section 16 while rounded into an elliptical shape as shown in FIG. 1. When this is carried out, plural rotation rolls disposed on the inside of the elliptically shaped image-forming section 16 may be rotated at a uniform velocity. A thin image forming apparatus can be achieved by such a rotatable image-forming section 16 of an elliptically shape.

Image data is input from a computer or the like through the data-input portions 38, 40 and current-supply portion 42 as the image-forming section 16 is being rotated. The pixel regions 14 are selected according to the image data to form a latent image on the image-forming section 16. In the selected pixel regions 14 a voltage is applied according to a signal, charge is accumulated in the capacitor 34 (FIG. 3A), and in addition charge moves to the pixel electrode 36 and builds up therein. When this occurs a large electrical current can be made to flow even with a small voltage, switching each of the pixel regions ON/OFF, since the active layer 48 of the thin-film transistors 30, 32 is formed from a material including an oxide semiconductor. Since low voltage driving can be performed in this manner, when the charged particles 20 are attracted to the pixel regions, the scattering of the charged particles 20, caused by abnormal discharge when a high voltage is applied, can be effectively prevented.

The developing device 18 adjacent to the image-forming section 16 is of a rotary type, mounted rotatably with developer units 18Y, 18M, 18C, 18K that store charged particles 20 of toner or the like of respective colors yellow (Y), magenta (M), cyan (C), and black (K). Each of the developer units 18Y, 18M, 18C, 18K is capable of being placed in contact with, and separated from, the image-forming section 16 by rotation of the storage body. It should be noted that there are no particular limitations to the shape, particle size etc. of the charged particles 20, as long as particles are used that can be charged with the opposite charge to that accumulated in the pixel electrodes 36 of the pixel regions 14 and that are able to be electrostatically attracted to the pixel regions 14 (pixel electrodes 36).

When the image-forming section 16 on which a latent image has been formed rotates and any one of the developer units of the developing device 18 is in contact, or comes as close as possible thereto, then the charged particles 20 stored in this developer unit are selectively attracted to the pixel regions 14 that have been charged with the opposite charge thereto (FIG. 3B). The latent image formed by the pixel regions 14 on the substrate 12 can thereby be made visible in the selected color from Y, M, C or K. It should be noted that when images are being formed of a particular single color (for example black alone) then a single color developer unit may be provided in place of the above described rotary type developing device 18.

The electrostatically attracted charged particles 20 (toner image) on the pixel regions 14 that has passed the developing device 18 are transferred by the transfer roll 24 to a transfer receiving body 22 such as paper or the like, and can be furthermore fixed through fixing rolls 26a, 26b. The transferred and fixed image on the transfer receiving body 22 is of a high quality, without the scattering of charged particles 20 caused by high voltage driving. After transfer, before forming the next latent image, any charged particles 20 that have remained on the image-forming section 16 are removed by the cleaning member 28 and charge erasure of the pixel regions 14 is carried out.

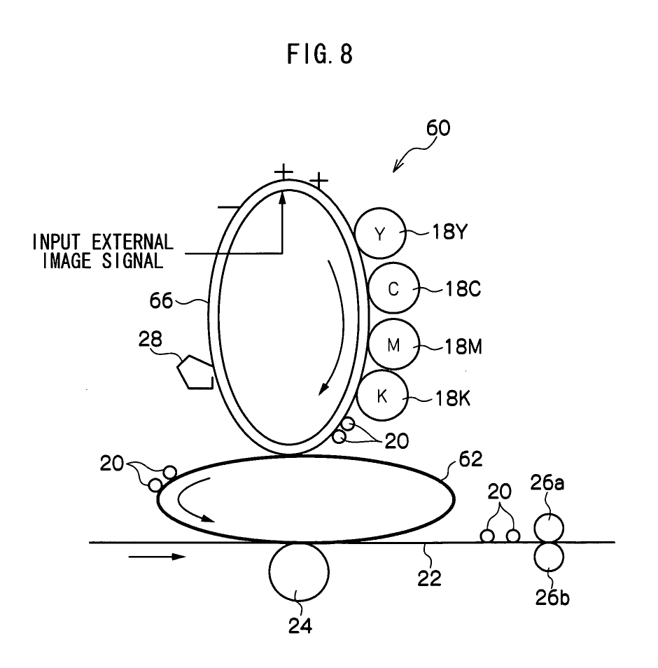

FIG. 8 schematically shows another example (second exemplary embodiment) of an image forming apparatus according to the present invention. With this image forming apparatus 60 there are developer units 18Y, 18C, 18M, 18K, corresponding to respective colors yellow (Y), cyan (C), magenta (M), and black (K), respectively disposed along the direction of travel of an image-forming section 66 so as to be contactable therewith. Also disposed therealong is an intermediate transfer body 62, for transferring the image formed on the image-forming section 66 by the charged particles 20 onto a transfer receiving body 22 such as paper. The configuration of the transfer roll 24, the cleaning member 28, the fixing rolls 26a, 26b etc. is similar to that shown in FIG. 1.

In the image forming apparatus 60 too, in a similar manner to that of the image forming apparatus 10 of the first exemplary embodiment, the image-forming section 66 is rotated and the pixel regions 14 are selectively charged based on externally input image data. Charged particles 20 from the developer units are electrostatically attached to the latent image formed on the image-forming section 66 to form an image. For example, external image data for each color is supplied to the pixel regions, and the images formed for each color of each of the developer units 18Y, 18C, 18M, 18K are temporarily transferred onto the intermediate transfer body 62. A color image is then obtainable by transferring all of the images superimposed on the intermediate transfer body 62 onto the transfer receiving body 22 such as paper. In this case too, a high quality color image is obtainable, without the scattering of the charged particles 20 that is caused by high voltage driving.

Explanation has been given above of the present invention, however, the present invention is not limited to the above exemplary embodiments. For example, the image-forming section is not limited to one of an elliptical shape, and a circular cylindrical shape or planar shape can also be used therefor.

In addition, explanation has been made in the exemplary embodiments of cases where an image is formed (made visible) by electrostatically attaching charged particles to an image-forming section, and this image is then transferred onto a transfer receiving body such as paper, however, the image forming apparatus of the present invention does not necessarily carry out transfer. For example, an image-forming section to which charged particles have been attached can be used as a display.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. An image forming apparatus comprising:
a substrate;
a plurality of pixel regions arrayed on the substrate;
an input portion that inputs image data to the pixel regions; and
an electrical supply portion that supplies charge to the pixel regions, the pixel regions each comprising:
a thin film transistor comprising a gate electrode, a gate insulating film, an active layer, a source electrode, and a drain electrode;
a capacitor that is electrically connected to the drain electrode and that accumulates charge; and
a pixel electrode that is electrically connected to the drain electrode and to the capacitor, such that charged particles are electrostatically attracted to a pixel region by movement of charge accumulated in the capacitor to the pixel electrode constituting the pixel region, and
the active layer of the thin film transistor being formed with a material that includes an oxide semiconductor.

2. The image forming apparatus of claim 1, wherein the substrate is a flexible substrate.

3. The image forming apparatus of claim 1, wherein the substrate is a transparent substrate.

4. The image forming apparatus of claim 1, wherein the active layer has at least a first region and a second region having electrical conductivity that is higher than that of the first region, the second region is in contact with the gate insulating film, and the first region is electrically connected to the second region and to at least one of the source electrode or the drain electrode.

5. The image forming apparatus of claim 1, wherein the oxide semiconductor is an oxide comprising at least one of In, Ga, or Zn.

6. The image forming apparatus of claim 1, wherein the electrodes are formed from a material comprising an oxide semiconductor.

7. The image forming apparatus of claim 1, wherein each of the pixel regions comprises a plurality of the thin film transistors.
